(19) United States
(12) Patent Application Publication
(10) Pub. No.: US 2005/0172900 A1
(43) Pub. Date: Aug. 11, 2005

(54) Coating apparatuses and jigs thereof

(75) Inventor: Sean Chang, Taoyuan Hsien (TW)

Correspondence Address: BIRCH STEWART KOLASCH & BIRCH, PO BOX 747, FALLS CHURCH, VA, 22040-0747, US

(73) Assignee: Delta Electronics, Inc.

(21) Appl. No.: 11/052,228

(22) Filed: Feb. 8, 2005

(30) Foreign Application Priority Data
Feb. 10, 2004 (TW) 93103028

(51) Int. Cl. C23C 16/00

(52) U.S. Cl. 118/719

(57) ABSTRACT

A coating apparatus and a jig thereof. The coating apparatus comprises a carrier and a jig. The jig surrounds the carrier and can be utilized to load an un-plated object. A hook-buckle structure connects the carrier and the jig. The jig comprises a holder and a fixing piece. The holder comprising at least one positioning piece, at least one loading area, at least one first protrusion, wherein the first protrusion serves as a sidewall of the loading area The fixing piece connecting to the holder and comprising at least an opening, wherein the opening overlaps the loading area, the size of the profile of the opening are relatively smaller than that of the loading area.

### BACKGROUND

The invention relates to coating apparatuses and jig thereof, and in particular to jigs for rapid assembly and disassembly of work pieces of coating apparatuses.

Optical components require coating to achieve optical performance. Optical coating apparatuses require relatively high coating speed and large capacity.

In a conventional 30-layer optical filter for an example, a conventional coating apparatus can only contain 60 to 70 2500 mm² optical substrates. The coating process is time-consuming, taking up to 6 to 8 hours. Thus the optical filter yield cannot be increased.

Another conventional coating apparatus can contain 400 2500 mm² optical substrates, with the coating process taking only 2 to 3 hours. Such coating apparatus can increase yield of the optical components and reduce fabrication time. In FIG. 1, a jig 100 of this conventional coating apparatus comprises a body 104 with a plurality of holes 102, a plurality of holders 106, and fixing plates 110 with an opening 108. For simplicity, only one holder and fixing plate are shown. The diameter of the flange 112 and the diameter of the openings 108 are relatively smaller than that of the holes 102.

Prior to the coating process, the fixing plates 110 are threaded on a top surface of the body 104 with the center of each opening 108 aligned each hole 102. Circular optical substrates are disposed in the hole 102, contacting the fixing plates 110. Pieces of optical substrates contacting the fixing plates 110 are defined as sputtering surfaces. The holders 106 are then inserted into the holes 102 and threaded on the opposite surface of the body 104. The optical substrates are, simultaneously, secured on the body 104 by the holders 106 and the fixing plates 110.

An end of the jig 100 is threaded on the coating apparatus for coating processes. The body 104, holders 106, optical substrates, and fixing plates 110 are disassembled subsequent to a coating process. The optical substrates can be replaced without removing the fixing plates 110 during a continuous process.

As screws are applied in the steps above, thousand threading steps are needed when the conventional coating apparatus is full loaded. Thus, the cost and the average consuming time for fabricating optical substrates are great.

Moreover, the shape and size of the holes are determined during fabrication of the bodies, thus limiting those of optical substrates. When the optical substrates are modified, new jigs must be provided. Thus, conventional coating apparatuses cannot effectively save fabrication time or cost.

### SUMMARY

Coating apparatuses and jigs in an embodiment of the invention can reduce cost, fabrication time, and time for connection of jigs and coating apparatuses.

An embodiment of the invention provides a coating apparatus and jigs for optical substrates of different sizes and shapes.

Another embodiment of the invention provides a jig for reducing installation time of work pieces installed in the jig.

An embodiment of the invention provides a coating apparatus comprising a chamber, at least one source region, a supply region, and a carrier. The source region connects the chamber to provide target material or plated material. The supply region connects the chamber to provide process material and air. The carrier is disposed in the chamber, and at least one jig is disposed on the carrier. The jig is utilized to carry at least one un-plated optical substrates. The jig is connected to the carrier by fastening means, such as buckles, wedges, or sleeves. The chamber is utilized to conduct physical or chemical vapor deposition processes.

An embodiment of a jig comprises a holder and a fixing piece. The holder comprising at least one positioning piece, at least one loading area, at least one first protrusion, wherein the first protrusion serves as a sidewall of the loading area The fixing piece connecting to the holder and comprising at least an opening, wherein the opening overlaps the loading area, the size of the profile of the opening are relatively smaller than that of the loading area.

Another embodiments of the coating apparatus comprise at least one carrier and at least one jig detachably disposed thereon. The jig used for load at least one substrate is connected to the carrier by fastening means, such as buckles, wedges, or sleeves.

In the described coating apparatus, the fastening means can be, for example, a resilient hook and buckle and can be disposed on the carrier or jigs by fasteners, such as rivets, screws, hooks, soldering, or integral formation as a single piece.

The jig further comprises a protrusion disposed between the fixing piece and the first positioning piece serving as a sidewall of the loading area. The protrusion connects the first positioning piece or the fixing piece by a rivet joint, lock, hook, wedge, soldering, or integral formation as a single piece. Meanwhile, the protrusion comprises a guide piece for guiding the un-plated object.

In the coating apparatus and the jig, a first protrusion and a second protrusion are respectively disposed on the opposite side of the loaded surface of the holder, the positions of the first and the second protrusions are corresponded, and the shapes of the first and the second protrusions are complementary.

Some embodiments of the carrier may also comprise at least one post piece, and two end plates respectively disposed on the two ends of the post piece. At least one of the end plates has a second positioning piece. A third positioning piece is disposed on one end of the jig corresponding to the second positioning piece. The second positioning piece is protrusive or recessed, and the third positioning piece is recessed and complementary to the second positioning piece.

Accordingly, the un-plated objects can be rapidly loaded on the jig, thus reducing loading time and coating process duration.

Furthermore, some embodiments of the jig may be capable of accommodating different sizes and types of the optical substrates or the pattern for plating by changing certain components.

Additionally, embodiments of the carrier and jigs are fixed by hooks or wedges. Thus, assembly time thereof can be greatly reduced, reducing delays in coating process and increasing yield.

### BRIEF DESCRIPTION OF THE DRAWINGS

Coating apparatus and jigs thereof can be more fully understood by reading the subsequent detailed description and examples with references made to the accompanying drawings, wherein:

FIG. 1 is a schematic view showing a conventional jig of a conventional coating apparatus;

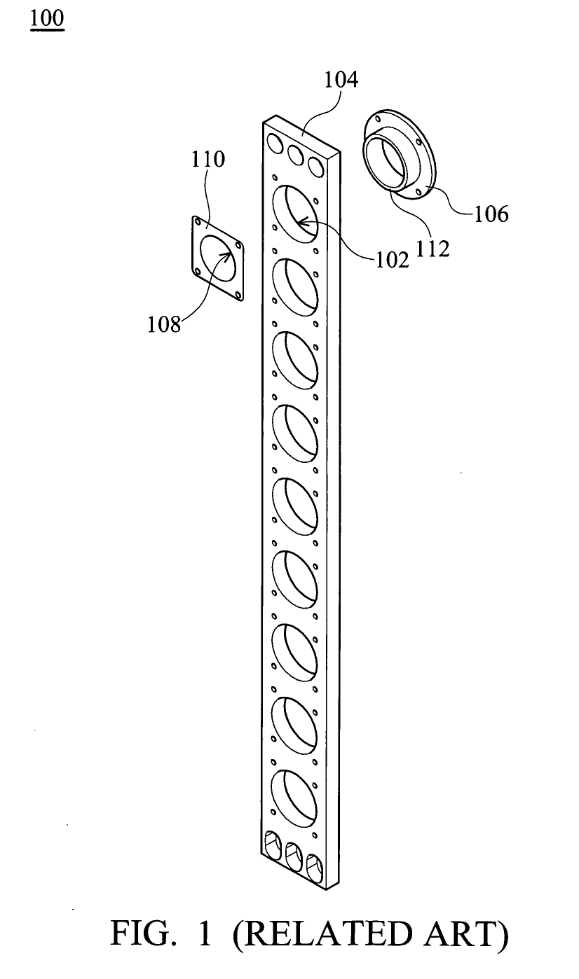

FIG. 2 is a schematic view of an embodiment of a coating apparatus; and

FIG. 3 is a schematic view of an embodiment of a jig.

### DETAILED DESCRIPTION

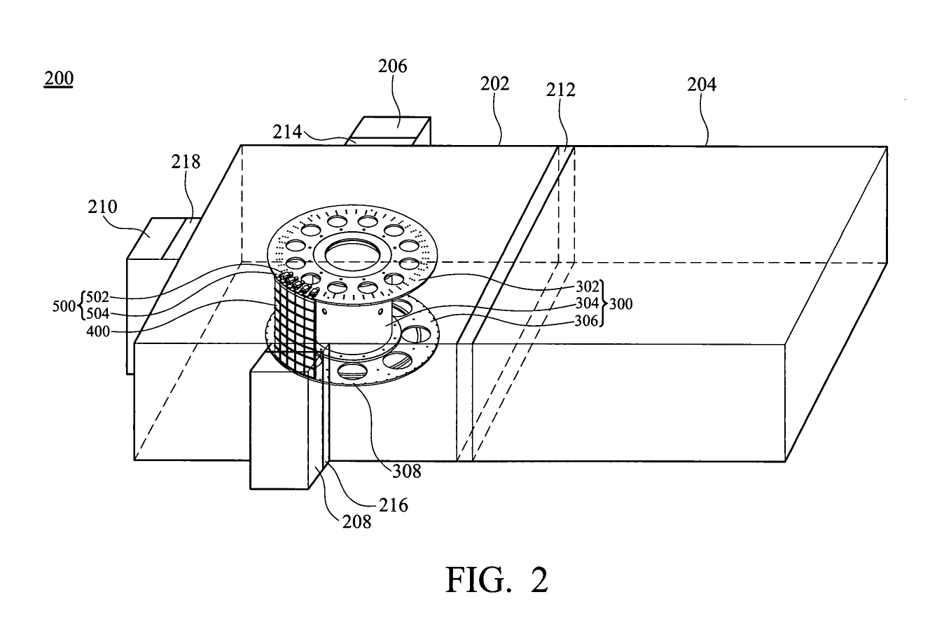

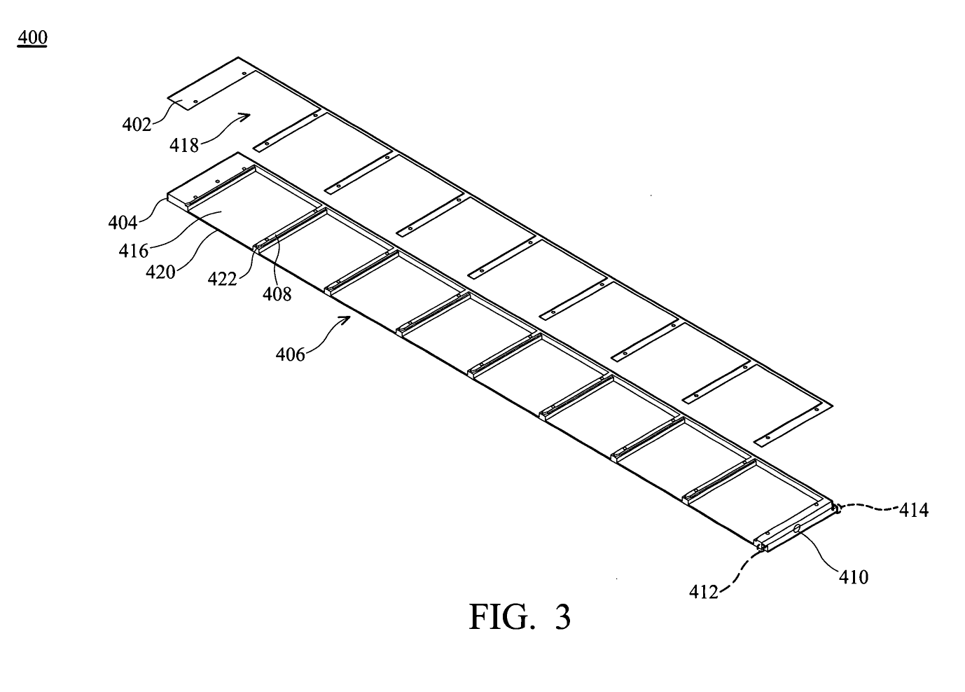

FIG. 2 is a schematic view of an embodiment of a coating apparatus 200. FIG. 3 is a schematic view of an embodiment of a jig 400. The coating apparatus 200 comprises a carrier 300, a jig 400 disposed around the carrier 300, a chamber 202, source regions 206 and 208, and a supply region 210, wherein the jig 400 and the carrier 300 are connected by latches 502 and 504 which may be a hook-buckle, a wedge, or a sleeve. The jig 400 and the carrier 300 can be connected by coupling. The jig 400 and the carrier 300 may be connected by fastener. The jig 400 is disposed around the carrier 300 for carrying at least one un-plated object.

The carrier 300 comprises a post piece 304 and two end plates 302 and 306 respectively disposed on the two ends of the post piece 304 to hold jig 400. The end plates 302 and 306 are attached to the ends of the post piece 304 by a rivet joint, lock, wedge, hook, soldering, or are integral formed as a single piece. The post piece 304 may be tubular, and a pattern or holes may be formed on the surface of the post piece 304. In addition, the post piece 304 may also be connected to a rotating means (not shown in figures) to rotate the carrier 300. The two ends of the jig 400 are disposed on the end plates 302, 306, and the position of the jig 400 is fixed. The end plates 302 and 306 may be circular or polygon plates. Patterns or holes may be formed on the surfaces of the end plates 302 and 306, and the end plates 302 and 306 may be metal, plastic, or low permeance material. Furthermore, at least one positioning piece 308 may be disposed on the edge of each end plate 302 and 306 to fasten the jig 400. The positioning piece 308 may be formed as a pin or a recessed piece.

The jig 400 comprises holder 406, positioning piece 404 disposed on the holder 406, and the fixing piece 402 disposed on the positioning piece 404, wherein fixing piece 402 and positioning piece 404 are disposed around to form a loading area 416. The size or shape of the profile of the loading area 416 are larger or equal to that of the un-plated object. The loading area 416 may be rectangular, circular, polygon, and so on.

The fixing piece 402 has opening 418. The opening 418 overlaps or partially overlaps the loading area 416, and the sizes or shapes of the profile of the opening are relatively smaller than that of the loading area 416. The fixing piece 402 is utilized to prevent the un-plated object from departing from the loading area 416 during the coating process. The shapes of the opening 418 and the loading area 416 may be the same or not. The shape and size of the profile of the opening 418 may be modified according to plated patterns, and thus the opening 418 may be rectangular, circular, polygonal, and so on.

The positioning piece 404 is disposed around the loading area 416, serving as a sidewall of the loading area 416, and has an access port 420 to transport the un-plated object. The positioning piece 404 is utilized to locate the un-plated object and prevent the object moving. A guide piece 422 may be formed on the edge of the access port 420 for guiding the un-plated object. Furthermore, the height of the positioning piece 404 may be higher or equal to the thickness of the un-plated object.

A protrusion 408 may also disposed on a surface of the positioning piece 404, and the other surface of the positioning piece 404 is connected to the holder 406, wherein the protrusion 408 is connected to the fixing piece 402. The positioning piece 408 is disposed around the loading area 416 to be a sidewall of the loading area 416 and has an access port 420 to transport the un-plated object. The protrusion 408 is utilized locate the un-plated object and prevent the object moving. Moreover, a guide piece 422 may be formed on the edge of the access port 420 for guiding the un-plated object entering the loading area 416. Furthermore, the positioning piece 404 may also support the un-plated object, to prevent contact with the holder 406.

Furthermore, the protrusion 408 and the positioning piece 404 may be integrally formed as a single piece, or the protrusion 408 and the fixing piece 402 may be integrally formed as a single piece. The protrusion 408 may be attached to the positioning piece 404 or the fixing piece 402 by riveting, locking, wedging, hooking, soldering, or being integrally formed as a single piece.

The holder 406 is utilized to load with the positioning piece 404 and the fixing piece 402 which is disposed on the positioning piece 404, wherein the positioning piece 404 is attached on a loaded surface of the holder 406. At least one end of the holder 406 is connected to a fastening means 500 and fixed on the carrier 300 thereby. The connecting method of fastening means 500, holder 406 and the carrier 300 can be a riveting, locking, wedging, hooking, soldering, or being integrally formed as a single piece. In addition, the two ends of the holder 406 may be respectively provided with the fastening means 500. Alternatively, one end of the holder 406 may be provided with the fastening means 500 while the other end may be formed with a positioning piece 410 corresponding to the positioning point 308. The positioning piece 410 may be a pin or a recessed piece.

Protrusions 412 and 414 are formed on two end of the loaded surface of the holder 406 to potentially prevent a specific surface of the un-plated object from being plated. The positions of the protrusions 412 and 414 can be corresponded to each other on the different sides of loaded surface of the holder 406, and the shapes of the protrusions are complementary. When at least two holders are utilized, a protrusion 412 (414) of one holder may be assembled a protrusion 414 (412) of the other holder. As a result, a specific surface of the un-plated object may potentially be prevented from being plated. The protrusions 412 and 414 may be also barriers to potentially prevent departure of the un-plated object from the jig 400 during rotation in the coating process.

The holder 406, positioning piece 404, and the fixing piece 402 may be integrally formed as a single piece or demountable. The holder 406, positioning piece 404, and the fixing piece 402 may be assembled by a riveting, locking, wedging, hooking, soldering, or being integrally formed as a single piece. The holder 406, positioning piece 404, and the fixing piece 402 may be metal, plastic, or low permeance material.

When the holder 406 is demounted from the positioning piece 404 and the fixing piece 402, the loading area 416 may be modified by using different positioning pieces 404 and the fixing pieces 402 to adapt to different coating requirement. Moreover, the size and shape of the loading area 416 and the pattern for plating may be changes by using different fixing pieces 402.

The chamber 202 is utilized to contain carrier 300 and to execute the coating process. The source regions 206 and 208 are disposed around the chamber 202. The supply region 210 connects the chamber 202 to provide process material and air. A buffer chamber 204 is disposed around the chamber 202 for pre-adjusting environmental factors in the chamber 202 when the carrier 300 enters or leaves the chamber 202. A plurality of gates 212, 214, 216, and 218 are disposed between the chamber 202 and the source regions 206 and 208, the supply region 210, and the buffer chamber 204 to respectively control the communication of the chamber 202 and the source regions 206, 208, the supply region 210, and the buffer chamber 204.

A physical or chemical vapor deposition process may be executed in the chamber, such as sputtering or evaporating. The target material and plated material in the source region 206 and 208, the process material and gas in the supply region 210, and the position of the source region 206 and 208 and the supply region 210 are according to requirement.

Accordingly, the un-plated objects can be rapidly loaded on the jig, thus reducing loading time and coating process duration.

Furthermore, some embodiments of the jig may be suitable for different types of the un-plated object or the pattern for plating by changing some components. Thus, the cost of the coating process may be also reduced.

In addition, the carrier and the jig are attached by hooks or wedges, so that the assembly time and delay time of the coating process may be greatly reduced and yield may be increased potentially.

While the invention has been described by way of example and in terms of the preferred embodiments, it is to be understood that the invention is not limited thereto. To the contrary, it is intended to cover various modifications and similar arrangements (as would be apparent to those skilled in the art). Therefore, the scope of the appended claims should be accorded the broadest interpretation so as to encompass all such modifications and similar arrangements.

1. A coating apparatus, comprising:
a carrier; and
a jig disposed around the carrier, wherein the jig and the carrier are connected by a hook-buckle structure, a wedge structure, or a sleeve structure.

2. The coating apparatus as claimed in claim 1, wherein the hook-buckle structure is a resilient hook and buckle.

3. The coating apparatus as claimed in claim 1, wherein the hook-buckle structure, the wedge structure, or the sleeve structure is disposed on the jig or the carrier by riveting, locking, wedging, hooking, soldering, or being integrally formed as a single piece.

4. The coating apparatus as claimed in claim 1, wherein the jig comprises:
a holder comprising at least one first positioning piece, at least one loading area, at least one first protrusion, wherein the first protrusion serves as a sidewall of the loading area; and
at least one fixing piece connecting to the holder and comprising at least an opening, wherein the opening overlaps the loading area, the size of the profile of the opening are relatively smaller than that of the loading area.

5. The coating apparatus as claimed in claim 4, wherein the shape of the loading area is rectangular, circular, or polygonal.

6. The coating apparatus as claimed in claim 4, wherein at least one end of the holder has a hook-buckle structure, a wedge structure, a sleeve structure or a locking structure to connect the carrier.

7. The coating apparatus as claimed in claim 4, wherein the first protrusion comprises a guide piece for guiding an un-plated object.

8. The coating apparatus as claimed in claim 4, wherein the first positioning piece comprises a guide piece for guiding an un-plated object.

9. The coating apparatus as claimed in claim 4, wherein an end of the holder has a pin or a recessed piece.

10. The coating apparatus as claimed in claim 4, wherein a second protrusion and a third protrusion are respectively disposed on the opposite side of the holder, the positions of the third and the second protrusions correspond to each other, and the shapes of the third and the second protrusions are complementary.

11. The coating apparatus as claimed in claim 1, wherein the carrier comprises:
at least one post piece; and
two end plates respectively disposed on the two ends of the post piece.

12. The coating apparatus as claimed in claim 11, wherein at least one of the end plates has a second positioning piece; a third positioning piece is disposed on the an end of the jig corresponding to the second positioning piece; and the second and third positioning pieces are complementary protrusive and recessed pieces.

13. The coating apparatus as claimed in claim 1, further comprising:
a chamber for containing the carrier and executing a physical or chemical vapor deposition process;
at least one source region connecting to the chamber to provide a target material or a plated material; and
at least one supply region connecting to the chamber to provide a processing material or air.

14. A jig for carrying at least one un-plated object, comprising:
a holder comprising at least one positioning piece, at least one loading area, at least one first protrusion, wherein the first protrusion serves as a sidewall of the loading area; and
at least one fixing piece connecting to the holder and comprising at least an opening, wherein the opening overlaps the loading area, the size of the profile of the opening are relatively smaller than that of the loading area.

15. The jig as claimed in claim 14, wherein at least one end of the holder has a hook-buckle structure, a wedge structure, or a sleeve structure.

16. The jig as claimed in claim 14, wherein the shape of the loading area is rectangular, circular, or polygonal.

17. The jig as claimed in claim 14, wherein the first protrusion comprises a guide piece for guiding the un-plated object.

18. The jig as claimed in claim 14, wherein an end of the holder has a pin or a recessed piece.

19. The jig as claimed in claim 14, wherein a second protrusion and a third protrusion are respectively disposed on the opposite sides of the holder, the positions of the third and the second protrusions match with each other, and the shapes of the third and the second protrusions are complementary.

20. A coating apparatus, comprising:
a carrier; and
a jig coupled to the carrier and comprising:
a holder comprising at least one positioning piece, at least one loading area, at least one first protrusion, wherein the first protrusion serves as a sidewall of the loading area; and
at least one fixing piece connecting to the holder and comprising at least an opening, wherein the opening overlaps the loading area, the size of the profile of the opening are relatively smaller than that of the loading area.
